(19) United States
(12) Patent Application Publication
(10) Pub. No.: US 2023/0024009 A1
(43) Pub. Date: Jan. 26, 2023

(54) FACE-UP WAFER EDGE POLISHING APPARATUS

(71) Applicant: Applied Materials, Inc., Santa Clara, CA (US)

(72) Inventors: Kevin H. Song, San Jose, CA (US); Benedict W. Pang, Burlingame, CA (US)

(73) Assignee: Applied Materials, Inc., Santa Clara, CA (US)

(21) Appl. No.: 17/380,788

(22) Filed: Jul. 20, 2021

(51) Int. Cl. H01L 21/687; H01L 21/306; B24B 37/20

(52) U.S. Cl. CPC H01L 21/68735; H01L 21/30625; B24B 37/20

(57) ABSTRACT

Exemplary substrate edge polishing apparatuses may include a chuck body defining a substrate support surface. The apparatuses may include an edge ring seated on the chuck body. The apparatuses may include a retaining wall disposed radially outward of the edge ring. The apparatuses may include a slurry delivery port disposed radially inward of the retaining wall. The apparatuses may include a cylindrical spindle that is positionable over the chuck body. The apparatuses may include an annular polishing pad coupled with a lower end of the cylindrical spindle.

### TECHNICAL FIELD

The present technology relates to semiconductor systems, processes, and equipment. More specifically, the present technology relates to polishing film deposited on a substrate.

### BACKGROUND

An integrated circuit is typically formed on a substrate by the sequential deposition of conductive, semiconductive, and/or insulative layers on a silicon wafer. A variety of fabrication processes use the planarization of a layer on the substrate between processing steps. For example, for certain applications, e.g., polishing of a metal layer to form vias, plugs, and/or lines in the trenches of a patterned layer, an overlying layer is planarized until the top surface of a patterned layer is exposed. In other applications, e.g., planarization of a dielectric layer for photolithography, an overlying layer is polished until a desired thickness remains over the underlying layer.

Chemical mechanical polishing (CMP) is one common method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. Abrasive polishing slurry is typically supplied to the surface of the polishing pad.

One problem in CMP is uniformly polishing the entire surface of the substrate. Oftentimes, due to the design of CMP systems the regions of the polishing pad proximate the peripheral edges of the polishing pad may flex, which may lead to uneven polishing. As a result, film thickness at the edge of the substrate is often greater than a middle portion of the substrate. This film non-uniformity may cause lithography issues and may lead to a loss in die yield from a given substrate.

Thus, there is a need for improved systems and methods that can be used to polish substrates to generate a uniform film across an entire surface area of the substrate. These and other needs are addressed by the present technology.

### SUMMARY

Exemplary substrate edge polishing apparatuses may include a chuck body defining a substrate support surface. The apparatuses may include an edge ring seated on the chuck body. The apparatuses may include a retaining wall disposed radially outward of the edge ring. The apparatuses may include a slurry delivery port disposed radially inward of the retaining wall. The apparatuses may include a spindle that is positionable over the chuck body. The apparatuses may include an annular polishing pad coupled with a lower end of the spindle.

In some embodiments, an inner diameter of the annular polishing pad may be less than an inner diameter of the edge ring. The spindle may be rotatable and laterally translatable relative to the chuck body. A height of a top surface of the edge ring may be within about 10 microns of a height of a substrate positioned on the substrate support surface. The apparatuses may include a slurry drainage port positioned within one or both of the chuck body and the retaining wall. An outer edge of the edge ring may be positioned against an inner surface of the retaining wall. The edge ring may be removably coupled with the chuck body.

Some embodiments of the present technology may encompass substrate edge polishing apparatuses. The apparatuses may include a chuck body defining a substrate support surface. The apparatuses may include an edge ring seated on the chuck body. The edge ring may have an inner diameter that is less than about 5% larger than a diameter of substrate support surface. The apparatuses may include a spindle that is positionable over the chuck body. The apparatuses may include a rotation drive mechanism coupled with the spindle. The apparatuses may include an annular polishing pad coupled with a lower end of the spindle.

In some embodiments, the annular polishing pad may include a CMP polishing pad or an abrasion disk. A top surface of the edge ring may taper toward an outer periphery of the edge ring. A bottom surface of the annular polishing pad may taper toward an outer periphery of the annular polishing pad. The chuck body may include an electrostatic chuck or a vacuum chuck. The apparatuses may include a retaining wall disposed radially outward of the edge ring. The apparatuses may include a polishing slurry source. The apparatuses may include a slurry delivery port fluidly coupled with the polishing slurry source. The slurry delivery port may be disposed radially inward of the retaining wall. A top surface of the substrate support surface may be concave or convex. The substrate edge polishing apparatus may be disposed within a polishing chamber that includes a face down polishing station.

Some embodiments of the present technology may encompass methods of polishing a substrate. The methods may include positioning a substrate face up within an open interior of an edge ring disposed atop a substrate support surface of a chuck body. The methods may include clamping the substrate to the chuck body. The methods may include engaging a top surface of the substrate with an annular polishing pad. The methods may include rotating the annular polishing pad against the top surface of the substrate.

In some embodiments, the methods may include laterally translating the annular polishing pad while rotating the annular polishing pad against the top surface of the substrate. The methods may include delivering a polishing slurry to the top surface of the substrate. The methods may include applying downward force to the annular polishing pad while rotating the annular polishing pad against the top surface of the substrate. A central axis of the annular polishing pad may be offset from a central axis of the substrate while rotating the annular polishing pad against the top surface of the substrate. The methods may include re-surfacing the annular polishing pad.

Such technology may provide numerous benefits over conventional systems and techniques. For example, the edge polishing apparatuses described herein may enable the edge regions of a substrate to be targeted during polishing operations. Oftentimes, the edge polishing techniques described herein may be used before and/or after a conventional CMP operation. This may enable the film thickness uniformity to be improved across the surface of the substrate, which may lead to increased die yield. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary polishing system according to some embodiments of the present technology.

FIG. 2 shows a schematic partial cross-sectional view of an exemplary edge processing apparatus according to some embodiments of the present technology.

FIG. 3 shows a schematic partial cross-sectional view of an exemplary edge processing apparatus according to some embodiments of the present technology.

FIG. 4 shows a schematic partial cross-sectional view of an exemplary refinishing station according to some embodiments of the present technology.

FIG. 5 shows a schematic partial top plan view of an exemplary polishing chamber according to some embodiments of the present technology.

FIG. 6 is a flowchart of an exemplary method of polishing a substrate according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In conventional chemical mechanical polishing (CMP) operations it is often difficult to uniformly polish the surface of a substrate. Conventional CMP polishing involves a substrate being positioned face down on a polishing pad, with a carrier that holds the substrate against a rotating polishing pad. However, the polishing pads often flex near the edges of the substrate, which may lead to higher film thicknesses remaining at the edge regions of the substrate. These issues may result in non-uniformity issues that result in a lower die yield.

The present technology overcomes these issues with conventional polishing systems by providing edge polishing apparatus that may be used to polish the film within the edge regions of a substrate. Embodiments may provide face-up polishing techniques that enable an annularly shaped polishing pad to selectively polish the edge regions of the wafer. These techniques may be used in conjunction with conventional CMP systems to produce substrates with improved film thickness uniformity. Additionally, embodiments may include chuck mechanisms that may help flatten a substrate during polishing, which may further improve the uniformity achieved during the polishing operation. Embodiments may enable the polishing pad to translate laterally relative to the substrate, which may enable the edge polishing apparatus to improve asymmetric uniformity issues.

Although the remaining disclosure will routinely identify specific film polishing processes utilizing the disclosed technology, it will be readily understood that the systems and methods are equally applicable to a variety of other semiconductor processing operations and systems. Accordingly, the technology should not be considered to be so limited as for use with the described polishing systems or processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems, along with any number of modifications, some of which will be noted below.

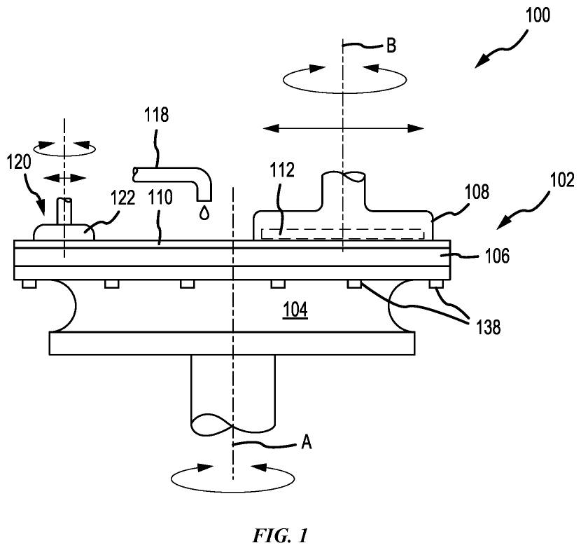

FIG. 1 shows a schematic cross-sectional view of an exemplary polishing system 100 according to some embodiments of the present technology. Polishing system 100 includes a platen assembly 102, which includes a lower platen 104 and an upper platen 106. Lower platen 104 may define an interior volume or cavity through which connections can be made, as well as in which may be included end-point detection equipment or other sensors or devices, such as eddy current sensors, optical sensors, or other components for monitoring polishing operations or components. For example, and as described further below, fluid couplings may be formed with lines extending through the lower platen 104, and which may access upper platen 106 through a backside of the upper platen. Platen assembly 102 may include a polishing pad 110 mounted on a first surface of the upper platen. A substrate carrier 108, or carrier head, may be disposed above the polishing pad 110 and may face the polishing pad 110. The platen assembly 102 may be rotatable about an axis A, while the substrate carrier 108 may be rotatable about an axis B. The substrate carrier may also be configured to sweep back and forth from an inner radius to an outer radius along the platen assembly, which may, in part, reduce uneven wear of the surface of the polishing pad 110. The polishing system 100 may also include a fluid delivery arm 118 positioned above the polishing pad 110, and which may be used to deliver polishing fluids, such as a polishing slurry, onto the polishing pad 110. Additionally, a pad conditioning assembly 120 may be disposed above the polishing pad 110, and may face the polishing pad 110.

In some embodiments of performing a chemical-mechanical polishing process, the rotating and/or sweeping substrate carrier 108 may exert a downforce against a substrate 112, which is shown in phantom and may be disposed within or coupled with the substrate carrier. The downward force applied may depress a material surface of the substrate 112 against the polishing pad 110 as the polishing pad 110 rotates about a central axis of the platen assembly. The interaction of the substrate 112 against the polishing pad 110 may occur in the presence of one or more polishing fluids delivered by the fluid delivery arm 118. A typical polishing fluid may include a slurry formed of an aqueous solution in which abrasive particles may be suspended. Often, the polishing fluid contains a pH adjuster and other chemically active components, such as an oxidizing agent, which may enable chemical mechanical polishing of the material surface of the substrate 112.

The pad conditioning assembly 120 may be operated to apply a fixed abrasive conditioning disk 122 against the surface of the polishing pad 110, which may be rotated as previously noted. The conditioning disk may be operated against the pad prior to, subsequent, or during polishing of the substrate 112. Conditioning the polishing pad 110 with the conditioning disk 122 may maintain the polishing pad 110 in a desired condition by abrading, rejuvenating, and removing polish byproducts and other debris from the polishing surface of the polishing pad 110. Upper platen 106 may be disposed on a mounting surface of the lower platen 104, and may be coupled with the lower platen 104 using a plurality of fasteners 138, such as extending through an annular flange shaped portion of the lower platen 104.

The polishing platen assembly 102, and thus the upper platen 106, may be suitably sized for any desired polishing system, and may be sized for a substrate of any diameter, including 200 mm, 300 mm, 450 mm, or greater. For example, a polishing platen assembly configured to polish 300 mm diameter substrates, may be characterized by a diameter of more than about 300 mm, such as between about 500 mm and about 1000 mm, or more than about 500 mm. The platen may be adjusted in diameter to accommodate substrates characterized by a larger or smaller diameter, or for a polishing platen 106 sized for concurrent polishing of multiple substrates. The upper platen 106 may be characterized by a thickness of between about 20 mm and about 150 mm, and may be characterized by a thickness of less than or about 100 mm, such as less than or about 80 mm, less than or about 60 mm, less than or about 40 mm, or less. In some embodiments, a ratio of a diameter to a thickness of the polishing platen 106 may be greater than or about 3:1, greater than or about 5:1, greater than or about 10:1, greater than or about 15:1, greater than or about 20:1, greater than or about 25:1, greater than or about 30:1, greater than or about 40:1, greater than or about 50:1, or more.

The upper platen and/or the lower platen may be formed of a suitably rigid, light-weight, and polishing fluid corrosion-resistant material, such as aluminum, an aluminum alloy, or stainless steel, although any number of materials may be used. Polishing pad 110 may be formed of any number of materials, including polymeric materials, such as polyurethane, a polycarbonate, fluoropolymers, polytetrafluoroethylene polyphenylene sulfide, or combinations of any of these or other materials. Additional materials may be or include open or closed cell foamed polymers, elastomers, felt, impregnated felt, plastics, or any other materials that may be compatible with the processing chemistries. It is to be understood that polishing system 100 is included to provide suitable reference to components discussed below, which may be incorporated in system 100, although the description of polishing system 100 is not intended to limit the present technology in any way, as embodiments of the present technology may be incorporated in any number of polishing systems that may benefit from the components and/or capabilities as described further below.

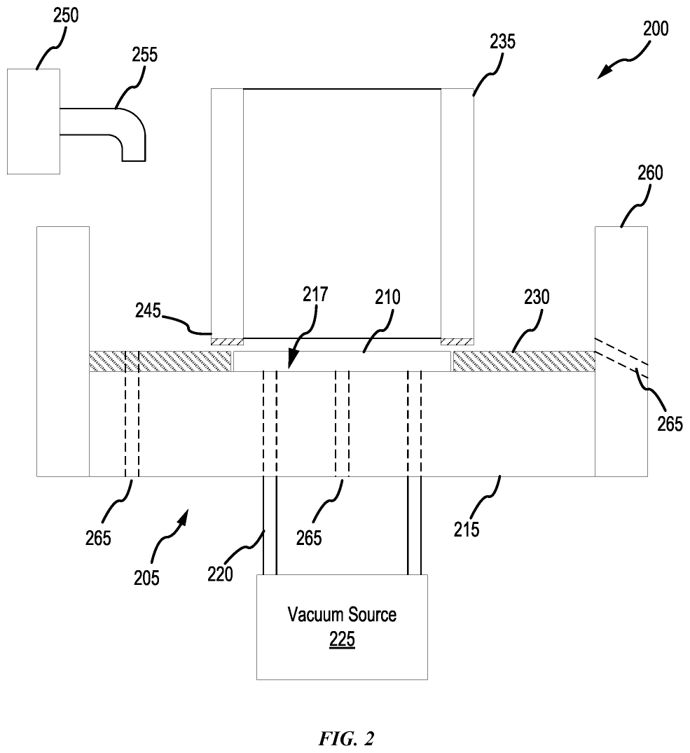

FIG. 2 illustrates a schematic cross-sectional view of an exemplary edge polishing apparatus 200 according to some embodiments of the present technology. The apparatus 200 may be used to perform edge polishing operations. Apparatus 200 may show a partial view of the components being discussed and that may be incorporated in a semiconductor processing system. Apparatus 200 may include a substrate support 205. Substrate support 205 may receive and support a substrate 210 during one or more processing operations. In some embodiments, the substrate support 205 may include a chuck body 215, which may define a substrate support surface 217. Chuck body 215 may include associated channels or components to operate as a vacuum chuck, an electrostatic chuck, and/or any other type of chucking system. For example, chuck body 215 may define a number of channels 220 that are coupled with a vacuum source 225. The vacuum source 225 may create a negative pressure within the channels 220 that clamp the substrate 210 to the chuck body.

In other embodiments, the chuck body 215 may include an electrostatic chuck. In such embodiments, the chuck body 215 may include associated channels or components to operate as an electrostatic chuck. For example, the electrostatic chuck body 215 may be formed from a conductive material (such as a metal like aluminum or any other material that may be thermally and or electrically conductive) and may be coupled with a source of electric power (such as DC power, pulsed DC power, RF bias power, a pulsed RF source or bias power, or a combination of these or other power sources) through a filter, which may be an impedance matching circuit to enable the electrostatic chuck body 215 to operate as an electrode. In other embodiments, a top portion of the electrostatic chuck body 215 may be formed from a dielectric material. In such embodiments, the electrostatic chuck body 215 may include separate electrodes which may be embedded within the chuck body 215 proximate the substrate support surface. Each electrode may be electrically coupled with a DC power source that provides energy or voltage to the electrode. In operation, a substrate 210 may be in at least partial contact with the substrate support surface of the chuck body, which may produce a contact gap, and which may essentially produce a capacitive effect between a surface of the pedestal and the substrate. Voltage may be applied to the contact gap, which may generate an electrostatic force for chucking.

An edge ring 230 may be seated atop the chuck body 215. For example, the edge ring 230 may be positioned about the substrate support surface 217 such that the substrate 210 is disposed within an open interior of the edge ring 230. The edge ring 230 may help maintain the substrate 210 in a desired position and may help prevent a polishing pad from deforming greatly if the polishing pad is moved beyond an outer periphery of the substrate 210. An inner diameter of the edge ring 230 may be less than or about 5% greater than a diameter of the substrate 210, less than or about 4% greater than a diameter of the substrate 210, less than or about 3% greater than a diameter of the substrate 210, less than or about 2% greater than a diameter of the substrate 210, less than or about 1% greater than a diameter of the substrate 210, less than or about 0.5% greater than a diameter of the substrate 210, or less. For example, for a substrate 210 having a diameter of 300 mm, the edge ring 230 may have an inner diameter ranging from at least 300 mm to about 315 mm, although oftentimes the inner diameter may be between or about 300.5 mm and 305 mm. A thickness of the edge ring 230 may substantially match a thickness of the substrate 210. For example, the thickness of the edge ring 230 may be within or about 3% of a thickness of the substrate 210, within or about 2% of a thickness of the substrate 210, within or about 1% of a thickness of the substrate 210, within or about 0.5% of a thickness of the substrate 210, or less. For example, for a substrate 210 having a thickness of 1 mm, the thickness of the edge ring 230 may be between or about 0.970 mm and 1.030 mm, between or about 0.980 mm and 1.020 mm, between or about 0.990 mm and 1.010 mm, between or about 0.995 mm and 1.005 mm, or about 1 mm. In some embodiments, a top surface of the chuck body 215 on which the edge ring 230 is seated may be raised or lowered. In such embodiments, a thickness of the edge ring 230 may be adjusted such that a top surface of the edge ring 230 is within or about 3% of a height of a top surface of the substrate 210, within or about 2% of the height of the top surface, within or about 1% of the height of the top surface, within or about 0.5% of the height of the top surface, or less.

The edge ring 230 may be detachably coupled with the chuck body 215. For example, one or more clamps, fasteners, and/or other coupling mechanisms may be used to secure the edge ring 230 to a top surface of the chuck body 215. This may enable the edge ring 230 to be removed for repair, cleaning, and/or replacement. For example, over a number of polishing operations, a top surface of the edge ring 230 may be polished to a lower height. To prevent impacts on subsequent polishing operations, the edge ring 230 may be replaced.

Apparatus 200 may include a spindle 235 that may be positionable over the chuck body 215. While shown here as having a hollow cylindrical body, the spindle 235 may be formed from other shapes and/or may be solid in various embodiments. The spindle 235 may be rotatable and translatable vertically and/or laterally relative to the chuck body 215. For example, the spindle 235 may be coupled with one or more motors and/or other drive mechanism 240 that may drive rotation and/or translation of the spindle 235. A bottom end of the spindle 235 may include a polishing pad 245. The polishing pad 245 may be removably coupled with the bottom end of the spindle 235, which may enable the polishing pad 245 to be refinished, cleaned, and/or replaced as needed. For example, the polishing pad 245 may be coupled with the bottom end of the spindle 235 using an adhesive (such as a pressure sensitive adhesive), snap connector, hook and loop connector, and/or other coupling mechanism that may enable the polishing pad 245 to be removably coupled with the spindle 235.

Polishing pad 245 may be a standard CMP polishing pad (which may be used with an abrasive slurry) and/or may be an abrasive disk, such as a grinding wheel that may be utilized without any slurry. The polishing pad 245 may have an annular shape that is sized such that the polishing pad 245 may polish only the peripheral edge regions of the substrate 210. For example, an inner diameter of the polishing pad 245 may be less than a diameter of the substrate 210 (and less than an inner diameter of the edge ring 230) and an outer diameter of the polishing pad 245 may be greater than the diameter of the substrate 210. For example, the inner diameter of the polishing pad 245 may be less than or about 90% of a diameter of the substrate 210, less than or about 91% of a diameter of the substrate 210, less than or about 92% of a diameter of the substrate 210, less than or about 93% of a diameter of the substrate 210, less than or about 94% of a diameter of the substrate 210, less than or about 95% of a diameter of the substrate 210, less than or about 96% of a diameter of the substrate 210, less than or about 97% of a diameter of the substrate 210, less than or about 98% of a diameter of the substrate 210, or less than or about 99% of a diameter of the substrate 210. For example, for a 300 mm substrate 210, the inner diameter of the polishing pad 245 may be between or about 270 mm and 297 mm, between or about 273 mm and 294 mm, between or about 276 mm and 291 mm, between or about 279 mm and 288 mm, or between or about 282 mm and 285 mm. The outer diameter of the polishing pad 245 may be greater than or about 100% of the diameter of the substrate 210, greater than or about 101% of the diameter of the substrate 210, greater than or about 102% of the diameter of the substrate 210, greater than or about 103% of the diameter of the substrate 210, greater than or about 104% of the diameter of the substrate 210, greater than or about 105% of the diameter of the substrate 210, greater than or about 106% of the diameter of the substrate 210, greater than or about 107% of the diameter of the substrate 210, greater than or about 108% of the diameter of the substrate 210, greater than or about 109% of the diameter of the substrate 210, greater than or about 110% of the diameter of the substrate 210, or more. For example, for a 300 mm substrate 210, the outer diameter of the polishing pad 245 may be between or about 300 mm and 330 mm, between or about 303 mm and 327 mm, between or about 306 mm and 324 mm, between or about 309 mm and 321 mm, between or about 312 mm and 318 mm, or about 315 mm. Such sizing may enable an entire edge region of the substrate 210 to be polished, and may also enable an asymmetric polishing of only a portion of the edge region of the substrate 210 if the spindle 235 and polishing pad 245 are translated laterally off-axis from a center of the substrate 210.

In some embodiments, such as those embodiments in which the polishing pad 245 is a CMP polishing pad, the apparatus 200 may include a slurry delivery tube 250. The slurry delivery port 250 may be coupled with a slurry source 255 and may deliver a slurry from the slurry source 255 to a surface of the substrate 210 during polishing operations. The slurry may include an aqueous solution in which abrasive particles may be suspended. To help keep the slurry from spreading out away from the substrate 210, apparatus 200 may include a retaining wall 260. Retaining wall 260 may be positioned radially outward of both the edge ring 230 and the slurry delivery port 250 such that any slurry delivered to the substrate 210 via the slurry delivery port 250 is kept proximate the substrate 210. While shown with slurry delivery port 250 being positioned above the retaining wall 260, in some embodiments the slurry delivery port 265 may extend through a portion of the retaining wall 260 and/or chuck body 215. To help minimize the amount of slurry needed for a given polishing operation, an inner surface of the retaining wall 260 may be position proximate to and may contact an outer surface of the edge ring 230 (although there may be a gap between the edge ring 230 and the retaining wall 260 in some embodiments). The retaining wall 260 may be formed integrally with chuck body 215 and/or may be a separate component that is later coupled with the chuck body 215. The retaining wall 260 may be coupled with an outer surface of the chuck body 215 as illustrated here and/or may be seated atop the chuck body 215 (similar to edge ring 230) in other embodiments. Apparatus 200 may include a slurry drainage port 265 that may be used to passively drain and/or actively pump slurry out of the area within the retaining wall 260 before, during, and/or after a given polishing operation. For example, the slurry drainage port 265 may extend through the retaining wall 260 and/or chuck body 215. In some embodiments, the slurry drainage port 265 may also extend through the edge ring 230. In such embodiments, the edge ring 230 may include one or more alignment features (such as pins) that ensure that the edge ring 230 is properly oriented on the chuck body 215 to align the portion of the slurry drainage port 265 on the edge ring 230 with the portion of the slurry drainage port 265 on the chuck body 215 and/or retaining wall 260. While shown with only a single slurry drainage port 265, it will be appreciated that multiple drainage ports may be used in various embodiments. For example, one or more slurry drainage ports 265 may be positioned radially outward of the substrate support surface 217 (such as outward of, through, and/or below the edge ring 230) and/or one or more slurry drainage ports 265 may extend through the substrate support surface 217. Such a configuration may better enable slurry to be removed from all areas of the chuck body 215. Where multiple slurry drainage ports 265 are positioned within a given area of the chuck body 215, the ports may be positioned at regular and/or irregular intervals about the chuck body 215.

While discussed primarily in the context of apparatuses using CMP polishing pads, it will be appreciated that the slurry source/port and/or retaining wall 260 may be present and/or utilized in some embodiments using an abrasive disk.

In operation, substrate 210 may be positioned face up within the open interior of the edge ring 230 atop the substrate support surface 217. A chucking force, such as a vacuum force and/or electrostatic chucking force, may be applied to the substrate 210 to clamp the substrate 210 to the substrate support surface 217. In some instances, in addition to clamping the substrate 210 to the substrate support surface 217, the chucking force may reduce and/or eliminate any bowing of the substrate 210 such that the substrate 210 is substantially flat prior to initiating any polishing operation. The spindle 235 and polishing pad 245 may be positioned over the edge region of the substrate 210. The polishing pad 245 may be positioned against the surface of the substrate 210 and may be rotated to polish film on the edge region of the substrate 210. Oftentimes, the spindle 235 and polishing pad 245 are rotated at a rate of between or about 60 rpm and 200 rpm, between or about 80 rpm and 180 rpm, between or about 100 rpm and 160 rpm, or between or about 120 rpm and 140 rpm, although other rates are possible in various embodiments. Downward force of the polishing pad 245 may be adjusted by the drive mechanism 240 based on the needs of a particular polishing operation. For example, the force may be adjusted between 0.5 psi and 10 psi, although other levels of force may be utilized in various embodiments. In some embodiments, the polishing pad 245 may be coaxially aligned with the substrate 210, which may be used to produce a symmetric polishing of the entire edge region of the substrate 210. In other embodiments, the polishing pad 245 may be offset from the central axis of the substrate 210, which may enable asymmetric polishing to be performed. In some embodiments, the polishing pad 245 (and spindle 235) may be laterally translated (or swept) during rotation of the polishing pad 245 to control the eccentricity of the polishing pad 245 to alter the polishing pattern of apparatus 200. Oftentimes, the lateral distance covered during sweeping may be less than or about 10 mm, less than or about 9 mm, less than or about 8 mm, less than or about 7 mm, less than or about 6 mm, less than or about 5 mm, less than or about 4 mm, less than or about 3 mm, less than or about 2 mm, less than or about 1 mm, or less. A rate of the sweeping motion may be adjusted based on the starting and/or desired film thickness profile.

In embodiments in which a CMP pad is used as polishing pad 245, a slurry may be delivered to the substrate 210. The slurry may include abrasive particles that provide grit that helps the CMP pad to polish the film on the substrate. Slurry may be delivered to the substrate 210 continuously and/or periodically via the slurry delivery port 255 and may be removed via the slurry drainage port 265.

Such operation of the apparatus 200 may enable the edge regions of the substrate 210 to be effectively polished to reduce non-uniformity issues. Additionally, by using a laterally translatable spindle 235, the apparatus 200 may be swept and/or otherwise translated to account for asymmetric non-uniformity issues that may be present prior to edge polishing. The use of an edge ring 230 having a top surface that is substantially aligned with the top surface of the substrate 210 may provide a relatively consistent polishing surface that extends radially outward of the substrate 210. This surface may help prevent deflection of the polishing pad 245 if a portion of the polishing pad 245 extends outward beyond the peripheral edge of the substrate 210 (which may occur if the outer diameter of the polishing pad 245 is larger than the diameter of the substrate 210 and/or if asymmetric polishing is being performed), which may ensure that the polishing pad does not significantly defect, which may help ensure that polishing forces are uniformly distributed across the edge regions of the substrate 210 to help evenly polish the edge regions. Edge polishing as described herein may be used in conjunction with convention CMP polishing operations to uniformly polish an entire film surface of a substrate. For example, the edge polishing may be performed before and/or after conventional face-down CMP polishing, which may enable an inner region of the substrate to be uniformly polished by the conventional CMP polishing and the edge region of the substrate to be polished to a similar degree using the edge polishing apparatus 200.

While discussed primarily for improving film uniformity at the edge regions, it will be appreciated that the techniques described herein may also be used to generate other film thickness profiles in some embodiments by providing the ability to tailor edge-polishing operations without affecting the polishing of the rest of a substrate.

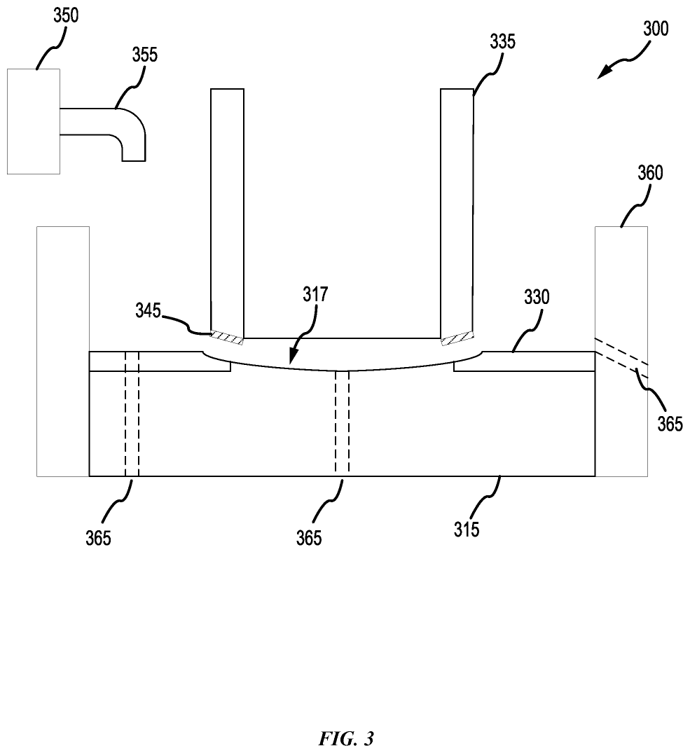

FIG. 3 shows a schematic partial cross-sectional view of an edge polishing apparatus 300 according to some embodiments of the present technology. As explained above, the present technology may be used in some embodiments to perform edge polishing operations. Apparatus 300 may be similar to apparatus 200, and may include any feature, component, or characteristic of the support described above, including any associated components. For example, apparatus 300 may include a chuck body 315 that defines a substrate support surface 317 on which a substrate may be positioned. Apparatus 300 may include an edge ring 330 seated on the chuck body 315, and may include a spindle 335 and polishing pad 345 for polishing the edge regions of the substrate. In some embodiments, the apparatus 300 may include a slurry source 350, one or more slurry delivery ports 355, a retaining wall 360, and/or one or more slurry drainage ports 365.

Apparatus 300 may be designed to polish substrates that are bowed to such a degree that the substrate may not be flattened without the risk of the substrate breaking. For example, the compressive and/or tensile stresses in the substrate may be very high due to the particular film chemistry deposited on the substrate. To accommodate such substrates, one or more of the components of the apparatus 300 may be contoured and/or otherwise tapered to match the shape of the substrate (or a shape of a partially flattened substrate). For example, the substrate support surface 317 may be contoured to have a concave or convex shape (depending on whether the substrate exhibits compressive or tensile bowing). The top surface of the edge ring 330 may be tapered (linearly or with a curve) toward an outer periphery of the edge ring 330. For example, if the substrate support surface 317 is concave (such as for tensile bowing), the top surface of the edge ring 330 may taper upward from the inner diameter to the outer diameter. If the substrate support surface 317 is convex (such as for compressive bowing), the top surface of the edge ring 330 may taper downward from the inner diameter to the outer diameter. A height of the top surface at the inner diameter may substantially match a height of the peripheral edge of the substrate to provide a substantially constant interface between top surfaces of the substrate and the edge ring 330.

The spindle 335 and/or polishing pad 345 may be modified to handle the bowed substrate 310. For example, the spindle 335 and/or polishing pad 345 may be tapered such that the bottom surface of the polishing pad 345 tapers (up or down to match a shape of the substrate and edge ring 330) toward an outer periphery of the polishing pad 345. This may enable the bottom polishing surface of the polishing pad 345 to be orientated substantially parallel to the edge region of the substrate to ensure that substantially tangential contact is made between the polishing pad 345 and substrate during polishing operations.

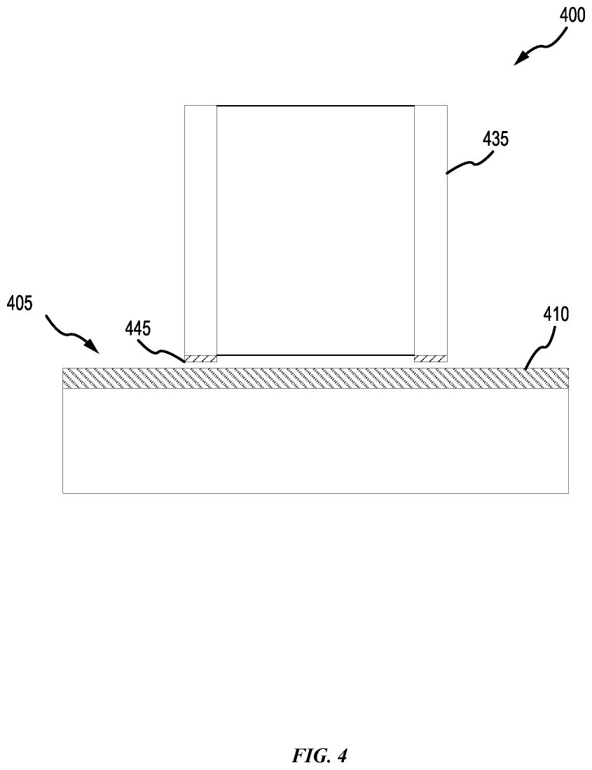

FIG. 4 illustrates a schematic partial cross-sectional view of a refinishing station 400 according to some embodiments of the present technology. The refinishing station 400 may be used to refinish, condition, and/or clean the surface of a polishing pad 445, such as polishing pad 245 or 345 described herein. For example, the station 400 may include a pad conditioning assembly 405. In embodiments in which the polishing pad 445 is a CMP pad, the pad conditioning assembly 402 may include a fixed abrasive conditioning disk 410. A spindle 435 (such as spindle 235 or 335) may rotate the polishing pad 445 against the surface of the pad conditioning assembly 405 to abrade, rejuvenate, and/or remove polish byproducts and other debris from the polishing surface of the polishing pad 445. In embodiments in which the polishing pad 445 is an abrasive disk, the pad conditioning pad may include a diamond dresser or other grinding dresser than may be used to condition or dress the polishing surface of the polishing pad 445.

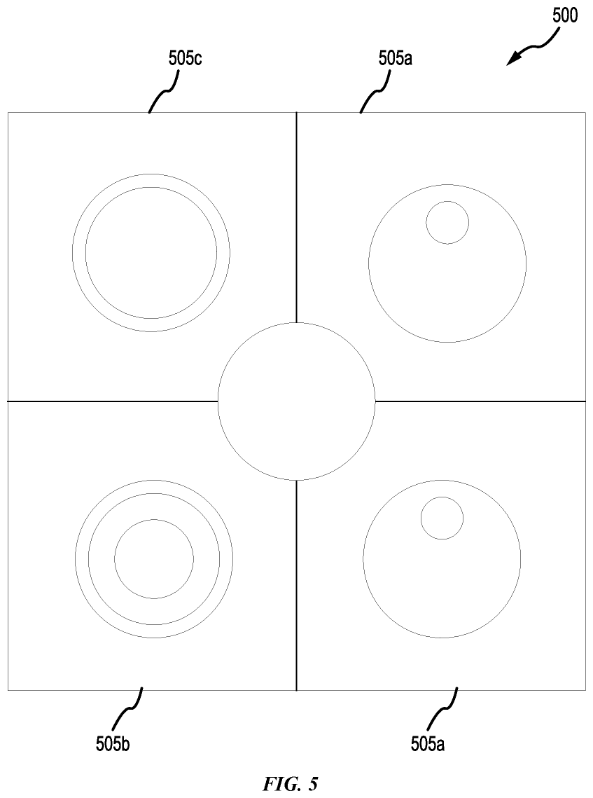

FIG. 5 illustrates a schematic top plan view of a polishing chamber 500 according to some embodiments of the present technology. Chamber 500 may include any number of stations 505, which may be used to perform one or more polishing operations. For example, chamber 500 may include at least or about 1 station, at least or about 2 stations, at least or about 3 stations, at least or about 4 stations, or more. Each station 505 may include one or more polishing systems. For example, the stations 505 may include one or more conventional CMP systems 505a (such as system 100), one or more edge polishing apparatuses 505b (such as apparatus 200 or 300), and/or one or more refinishing stations 505c (such as station 400). The various stations may be provided in any number, arrangement, and/or combination. As just one example, the chamber 500 may include two CMP stations 505a, one edge polishing apparatus 505b, and one refinishing station 505c. Chamber 500 may include one or more robots 510 that may be used to move substrates from one station 505 to another. For example, the robot 510 may transfer a substrate between one of the CMP stations 505a and the edge polishing apparatus 505b. A spindle of the edge polishing apparatus 505b may move the polishing pad between the edge polishing apparatus and the refinishing station.

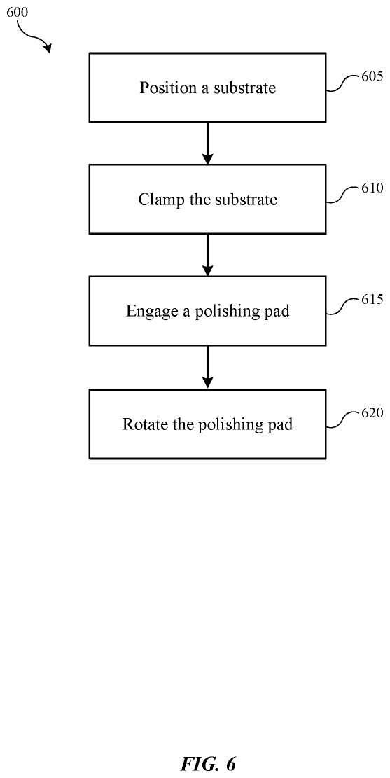

FIG. 6 shows exemplary operations in a method 600 for polishing a substrate according to some embodiments of the present technology. Method 600 may be performed using an edge polishing apparatus, such as edge polishing apparatus 200 or 300 described herein. Method 600 may include operations prior to the substrate polishing in some embodiments. For example, prior to the polishing, a substrate may have one or more deposition and/or etching operations performed as well as any planarization or other process operations performed. Method 600 may include a number of operations that may be performed automatically within a system to limit manual interaction, and to provide increased efficiency and precision over manual operations. Method 600 may be performed in conjunction with a conventional CMP polishing process. For example, the conventional CMP polishing process may be performed before and/or after method 600.

Method 600 may include positioning a substrate face up within an open interior of an edge ring disposed atop a substrate support surface of a chuck body of an edge polishing apparatus at operation 605. The substrate may be clamped to the chuck body at operation 610. For example, a chucking mechanism may be activated to provide a vacuum chucking force and/or an electrostatic chucking force that may clamp and/or flatten the substrate against the substrate support surface. A top surface of the substrate may be engaged with an annular polishing pad at operation 615. At operation 620, the annular polishing pad may be rotated against the top surface of the substrate to polish the edge region of the substrate. For example, a central axis of the polishing pad may be coaxial with a central axis of the substrate while rotating the annular polishing pad against the top surface of the substrate to uniformly polish the edge region. The central axis of the polishing pad may be offset from a central axis of the substrate while rotating the annular polishing pad against the top surface of the substrate to polish away asymmetric film thickness non-uniformity issues within the edge regions. In some embodiments, the annular polishing pad may be laterally translated, or swept, about the surface of the substrate while rotating the annular polishing pad against the top surface of the substrate to polish the substrate in a desired pattern and/or to achieve a desired film thickness profile. Downward force may be applied to the annular polishing pad while rotating the annular polishing pad against the top surface of the substrate. The magnitude of the downward force may be adjusted to control a rate of polishing of the edge polishing apparatus.

In some embodiments, such as embodiments in which a CMP pad is used as a polishing pad, the method 600 may include delivering a slurry to the substrate. The slurry may include abrasive particles that provide grit that helps the CMP pad to polish the film on the substrate. Slurry may be delivered to the substrate continuously and/or periodically via a slurry delivery port. Once a given polishing operation has been completed, the slurry may be removed from the apparatus, such as by draining and/or pumping the slurry via a slurry drainage port.

In some embodiments, the method 600 may include re-surfacing the annular polishing pad. For example, after one or more polishing operations the polishing pad may lose grit, become saturated with slurry and/or film debris, and/or may otherwise be unsuitable for further operation. In such embodiments, the spindle holding the polishing pad may maneuver the polishing pad into engagement with a pad conditioning assembly. The polishing pad may be rotated against the pad conditioning assembly to abrade the polishing surface, rejuvenate the polishing surface, remove polish byproducts and other debris from the polishing surface, and/or condition or dress the polishing surface of the polishing pad. Once re-surfaced, the polishing pad may be returned to service to polish one or more additional substrates.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a heater” includes a plurality of such heaters, and reference to “the protrusion” includes reference to one or more protrusions and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A substrate edge polishing apparatus, comprising:
a chuck body defining a substrate support surface;
an edge ring seated on the chuck body;
a retaining wall disposed radially outward of the edge ring;
a slurry delivery port disposed radially inward of the retaining wall;
a spindle that is positionable over the chuck body; and
an annular polishing pad coupled with a lower end of the spindle.

2. The substrate edge polishing apparatus of claim 1, wherein:
an inner diameter of the annular polishing pad is less than an inner diameter of the edge ring.

3. The substrate edge polishing apparatus of claim 1, wherein:
the spindle is rotatable and laterally translatable relative to the chuck body.

4. The substrate edge polishing apparatus of claim 1, wherein:
a height of a top surface of the edge ring is within about 10 microns of a height of a substrate positioned on the substrate support surface.

5. The substrate edge polishing apparatus of claim 1, further comprising:
a slurry drainage port positioned within one or both of the chuck body and the retaining wall.

6. The substrate edge polishing apparatus of claim 1, wherein:
an outer edge of the edge ring is positioned against an inner surface of the retaining wall.

7. The substrate edge polishing apparatus of claim 1, wherein:
the edge ring is removably coupled with the chuck body.

8. A substrate edge polishing apparatus, comprising:
a chuck body defining a substrate support surface;
an edge ring seated on the chuck body, the edge ring having an inner diameter that is less than about 5% larger than a diameter of substrate support surface;
a spindle that is positionable over the chuck body;
a rotation drive mechanism coupled with the spindle; and
an annular polishing pad coupled with a lower end of the spindle.

9. The substrate edge polishing apparatus of claim 8, wherein:
the annular polishing pad comprises a CMP polishing pad or an abrasion disk.

10. The substrate edge polishing apparatus of claim 8, wherein:
a top surface of the edge ring tapers toward an outer periphery of the edge ring; and
a bottom surface of the annular polishing pad tapers toward an outer periphery of the annular polishing pad.

11. The substrate edge polishing apparatus of claim 8, wherein:
the chuck body comprises an electrostatic chuck or a vacuum chuck.

12. The substrate edge polishing apparatus of claim 8, further comprising:
a retaining wall disposed radially outward of the edge ring;
a polishing slurry source; and
a slurry delivery port fluidly coupled with the polishing slurry source, the slurry delivery port being disposed radially inward of the retaining wall.

13. The substrate edge polishing apparatus of claim 8, wherein:
a top surface of the substrate support surface is concave or convex.

14. The substrate edge polishing apparatus of claim 8, wherein:
the substrate edge polishing apparatus is disposed within a polishing chamber that comprises a face down polishing station.

15. A method of polishing a substrate, comprising:
positioning a substrate face up within an open interior of an edge ring disposed atop a substrate support surface of a chuck body;
clamping the substrate to the chuck body;
engaging a top surface of the substrate with an annular polishing pad; and
rotating the annular polishing pad against the top surface of the substrate.

16. The method of polishing a substrate of claim 15, further comprising:
laterally translating the annular polishing pad while rotating the annular polishing pad against the top surface of the substrate.

17. The method of polishing a substrate of claim 15, further comprising:
delivering a polishing slurry to the top surface of the substrate.

18. The method of polishing a substrate of claim 15, further comprising:
applying downward force to the annular polishing pad while rotating the annular polishing pad against the top surface of the substrate.

19. The method of polishing a substrate of claim 15, wherein:
a central axis of the annular polishing pad is offset from a central axis of the substrate while rotating the annular polishing pad against the top surface of the substrate.

20. The method of polishing a substrate of claim 15, further comprising:
re-surfacing the annular polishing pad.
